(19) United States
(12) Patent Application Publication
(10) Pub. No.: US 2008/0290084 A1
(43) Pub. Date: Nov. 27, 2008

(54) Method of Forming a Flexible Heating Element

(76) Inventors: Christopher J. Winscom, Cambridgeshire (GB); John R. Fyson, London (GB); Peter Hewitson, Middlesex (GB); Christopher B. Rider, Cambridgeshire (GB); Sean D. Slater, Cambridgeshire (GB)

Correspondence Address: EASTMAN KODAK COMPANY;PATENT LEGAL STAFF, 343 STATE STREET, ROCHESTER, NY, 14650-2201, US

(21) Appl. No.: 12/066,401

(22) PCT Filed: Sep. 7, 2006
(86) PCT No.: PCT/GB2006/003290

§ 371 Date: Mar. 11, 2008

(30) Foreign Application Priority Data
Sep. 13, 2005 (GB) 0518609.3

(51) Int. Cl. H05B 3/06; G03F 7/20

(52) U.S. Cl. 219/522; 430/319

(57) ABSTRACT

The present invention provides a method of manufacturing a heating element having a desired pattern of conductive tracks forming a power dissipative conductive track pattern with a desired resistivity and power output, the method comprising providing a photosensitive or pressure-sensitive element comprising: a support having coated on at least one side thereof a photo-sensitive or pressure-sensitive layer, which is capable of, upon imagewise radiation or pressure exposure according to the desired pattern and development of the resulting latent image, providing a metal image according to the desired pattern; imagewise radiative- or pressure-exposing the layer of the element according to a desired conductive pattern to form a latent image in the layer; and developing the element to form a conductive metal pattern, corresponding to the pattern of the latent image, on the support. The heating element may be formed on a flexible support and finds particular utility in heated window/windscreen applications.

### FIELD OF THE INVENTION

The present invention relates to the formation of heating elements on flexible supports for the purpose of providing heat to windows, windscreens etc. in order to reduce condensation or frost formed thereon and to improve transparency. The invention is particularly concerned with the formation of resistive metal tracks according to a desired pattern, whereby connection of each end of the track pattern to an appropriate power source enables the track pattern to provide a suitable and desirable heating effect to a substrate to which the track pattern is physically applied. The invention finds particular utility in heated window/windscreen applications.

### BACKGROUND OF THE INVENTION

Vehicles, e.g. automotive vehicles, railway locomotives, water-going crafts and aircrafts, require clear vision for their operators in all weathers. Personal outdoor equipment incorporating visors in some form have similar requirements. Certain items of optical equipment, e.g. remote outdoor security cameras or cooled photomultiplier housings embedded in more complex indoor equipment, are equipped with windows which must be free from water droplets, condensation, etc.

Heating of windows and windscreens, such as those of the above applications, to overcome and prevent problems associated with misting and frosting is required in order to provide the necessary clear vision. Typically, the necessary heating is achieved by applying a voltage across an imbedded circuitry or array of conductive wires in the windscreen or other transparent substrate to be heated, or across an electroconductive coating on the windscreen/substrate.

Generally, in applying a voltage across a heating element comprising an array of delicate wires or electroconductive coating to provide a heating effect to, for example, a windscreen, a source of electrical potential is connected to the heating element by a pair of bus bars spaced along opposite edges of the element to uniformly distribute the electrical energy therethrough. Typically, in order to protect the element, it is laminated between two sheets of transparent material so that the coating and bus bars are positioned between the two sheets, which also requires thin bus bars so as to avoid stress points in the lamination step. The automotive industry has produced various means of embedding heating elements in automotive windscreens.

U.S. Pat. No. 3,612,745 describes a flexible bus bar assembly including solid strips of an electrically conductive metal foil arranged in a laterally corrugated form to provide flexibility and responsiveness to thermal expansions and contractions. The strips are embedded within an interlayer film and covered with an electrically conductive metallo-thermoplastic tape, the film being subsequently coated in an electroconductive coating to provide heating capability, and the interlayer film then laminated between two transparent sheets to form a transparent window. Difficulties with this method include the unsuitability for high current throughput applications and complex production of the tape.

U.S. Pat. No. 4,057,671 teaches a substantially all-metallic low temperature fusible bus bar paste consisting of a mixture of finely divided highly electro-conductive metal particles and finely divided low temperature fusible metal alloy particles which are fused in contact with an electroconductive circuit carried on a substrate. The technique is effective with low temperature substrates, but the elongated strips of paste have a high resistance lengthwise which can affect current distribution across the coated substrate.

U.S. Pat. No. 4,361,751 describes a transparent electroconductive window having an electroconductive pattern coated on a transparent (non-conductive) substrate with a bus bar comprising a current carrying member in the form of a wire mesh having a connection to a source of electric potential and an electroconductive layer, which is located between the current carrying mesh and the electroconductive coating. This provides a thin, flexible two-component bus bar having a low electrical resistance and the ability to uniformly distribute current through the electroconductive pattern (avoiding high current densities).

In applying a voltage across an electrical circuit or array of conductive wires to provide the requisite heating to the windscreen or other transparent substrate, it is again typical to laminate the circuit/array between two layers of the substrate, e.g. glass, to protect the fragile circuitry from shorting or physical damage. The wires used in such circuitry are particularly fragile as they have to be sufficiently thin to enable the substrate to remain effectively transparent to the user.

The minimum heat dissipation requirements for different types of vehicle are well known. Rail locomotives, sea-going vessels and aircraft have particularly robust dissipation requirements compared with that for cars, which typically require at least 4.5 W/dm². Other outdoor equipment involving goggles, visors, and cameras, and indoor equipment involving cooled photomultipliers and optical sensors, are expected to require no more than this level of dissipation to maintain windows free from condensation.

### PROBLEM TO BE SOLVED BY THE INVENTION

Transparent heating elements that involve the embedding of straight heating wires in the windscreen material suffer from non-evenly distributed heating and in the event of a break in one of the wires, a noticeable absence of heating in the affected areas. Continuous thin films of conductive oxides may provide evenly distributed heating, but for typical 12V supply voltages the conductivity required for adequate power dissipation requires films so thick that optical absorption becomes very significant or the system needs a secondary bus-bar system to supply current to smaller component areas of the screen. In either case, fabrication is expensive and does not achieve the desired power dissipation and optical clarity.

The invention aims to provide an economically produced, effectively transparent heating element, the materials of which are totally robust to dissipation levels of up to 10 W/dm² or greater.

### SUMMARY OF THE INVENTION

According to a first aspect of the invention, there is provided a method of manufacturing a heating element having a desired pattern of conductive tracks forming a power dissipative conductive track pattern with a desired resistivity and power output, the method comprising providing a photosensitive or pressure-sensitive element comprising: a support having coated on at least one side thereof, a photosensitive or pressure-sensitive layer, which is capable of, upon imagewise radiation or pressure exposure according to the desired pattern and development of the resulting latent image, providing a metal image according to the desired pattern; imagewise radiative- or pressure-exposing the layer of the element according to a desired conductive pattern to form a latent image in the layer; and developing the element to form a conductive metal pattern corresponding to the pattern of the latent image on the support.

According to a second aspect of the invention, there is provided a heating element obtainable by the above method.

According to a third aspect of the invention, there is provided a heating element for a vehicle windscreen comprising, over the area to be heated, a power dissipative conductive track pattern on a support substrate, which conductive track pattern is a conductive mesh with an optical transmission of at least 80%.

According to a fourth aspect of the invention, there is provided a heating element comprising a conductive track pattern on a support substrate, wherein the conductive track pattern comprises tracks having a width of 15 μm or less, wherein the element has a sheet resistance of 10 ohms/square or less and an optical transmission of greater than 90%.

According to a fifth aspect of the invention, there is provided the use of a photosensitive or pressure-sensitive imaging element in the manufacture of a heating element, wherein the element comprises a support substrate, a photosensitive or pressure-sensitive layer supported by the support substrate and comprising a photosensitive or pressure-sensitive metal salt dispersed in a binder composition.

According to a sixth aspect of the invention, there is provided an electrically heated window comprising a glass comprising at least two plies of transparent glazing material and a heating element comprising at least one ply of an interlayer material extending between the plies of glazing material, the interlayer material having on one or both sides thereof a conductive metal pattern formed according to the above method and a connecting means for connecting the heating element to a power supply.

### ADVANTAGEOUS EFFECT OF THE INVENTION

The heating element according to the present invention is more economical to produce than the known prior art. It is more effectively transparent than known prior art offering evenly-distributed heating. It is also sufficiently robust for the desired purposes and is not limited to being embedded in the windscreen. It may be a replaceable, separately mounted layer on the inner or outer surface of the windscreen or visor material for which it is intended to provide the heating effect.

Furthermore, the heating element according to the present invention may be produced on a separate transparent flexible support to the substrate to be heated and then subsequently laminated to the substrate to be heated, e.g. a windscreen. The method of the present invention provides a more economical method of producing suitable heating elements than the known prior art methods of providing evenly distributed heating.

The heating element of the present invention may be formed on a flexible support, enabling simple application to curved surfaces to be heated and ease of handling. It is furthermore capable of delivering a power dissipation of 5 W/d² without degradation and distortion of the materials. It is also capable of being lightweight, thereby leading to low installation and delivery costs. Fabrication of the heating elements according to the present invention also has the advantage of being a relatively simple process and of relatively low cost.

### BRIEF DESCRIPTION OF THE DRAWINGS

FIG. 1 is a diagrammatical representation of an apparatus used for monitoring the performance of a mesh produced in accordance with Example 2 below.

FIG. 2 is a circuit diagram of the circuit used in monitoring the performance of a mesh produced in accordance with Example 2 below.

FIG. 3 is graph of power dissipated versus surface conductivity for a mesh in accordance with Example 2 below.

FIG. 4 is a scanning electron micrograph of a mesh produced with an ultrasonic agitation step in accordance with Example 3 below.

FIG. 5 is a scanning electron micrograph of a mesh corresponding to that of FIG. 4, except that it was produced without the ultrasonic agitation step.

### DETAILED DESCRIPTION OF THE INVENTION

The present invention provides a heating element and method of producing a heating element, which comprises a power dissipative metal track pattern on an electrically non-conductive support substrate for use in a heating system for objects such as windscreens, which heating system typically comprises a power source (e.g. a 12V supply), a heating element and at least two connection points (e.g. bus-bars) for connecting the heating element to the power supply.

The method of the present invention involves generating a heating element having a desired pattern and dissipated power output for a particular application, whilst ideally retaining sufficient transmission of light to give an unobstructed view. The method involves generating a latent image through radiative or pressure exposure of a photosensitive or pressure-sensitive layer in the element according to a desired pattern, the layer typically comprising a metal salt in a binder, followed by development to form a corresponding metal pattern. The form and conductivity of the metal image may be improved, if desired, by plating the metal image by physical development (i.e. electroless plating) and/or electrochemical development (i.e. electroplating) as part of the development process. Preferably, the metal image formed by conventional development is capable of carrying a current (i.e. is conductive) and can be electroplated without needing an electroless plating step.

The support substrate upon which the photosensitive or pressure-sensitive material utilised may be coated depends upon the intended utility and may be any substrate to which a heating effect is desired or any suitable support substrate that may be laminated or otherwise applied to a windscreen or other object requiring heating. It may be rigid or flexible and should be transparent. Preferably, the support substrate is a transparent, flexible substrate and may enable the heating element to be applied to the subject to be heated to be a separately mountable, replaceable element that can be applied to the inner or outer surface of the subject (e.g. vehicle windscreen or visor).

Suitable such substrates include, for example, glass, glass-reinforced epoxy laminates, cellulose triacetate, acrylic esters, polycarbonates, adhesive-coated polymer substrates, polymer substrates and composite materials. Suitable polymers for use as polymer substrates include polyethylenes, especially polyethylene terephthalate (PET) and polyethylene naphthalate (PEN), polypropylenes, polyvinyl acetates, polyurethanes, polyesters, polyamides, polyimides, polysulfones and mixtures thereof. The substrate, especially a polymer substrate, may be treated to improve adhesion of the silver halide emulsion to the substrate surface. For example, the substrate may be coated with a polymer adhesive layer or the surface may be chemically treated or subjected to a corona treatment.

For coating onto a substrate in the manufacture of flexible electronic devices or components the support is preferably flexible, which aids rapid roll-to-roll application.

An Estar® PET support and a cellulose triacetate support are useful examples of flexible transparent supports.

Alternatively, the support may be the same support used in a flexible display device, by which it is meant that a photosensitive or pressure-sensitive coating may be coated onto a support for a display device and imaged in situ according to a desired pattern and processed in situ.

Where a discrete support is utilised (i.e. the support is not the reverse side of a support for a flexible display device), it can be coated with a photosensitive and/or a pressure-sensitive layer on either side or both sides, provided that either the same pattern is desired for both sides or the support is such that formation of the latent image on one side of the support will not fog the coating on the other side of the support.

The photosensitive or pressure-sensitive material may be any suitable material capable of providing a latent image (i.e. a germ or nucleus of metal in each exposed grain of metal salt) according to a desired pattern upon photo- or pressure-exposure and that comprises, for example, a photosensitive or pressure-sensitive metal salt, which is developable into a metal image, and a binder in which the metal salt can be dispersed.

Preferably, the binder is a hydrophilic colloid such as gelatin or gelatin derivative, polyvinyl alcohol (PVA), polyvinylpyrrolidone (PVP) or casein and may contain a further polymer. Suitable hydrophilic colloids and vinyl polymers and copolymers are described in Section IX of Research Disclosure Item 36544, September 1994, published by Kenneth Mason Publications, Emsworth, Hants, PO10 7DQ, UK. The preferred hydrophilic colloid is gelatin.

The photosensitive or pressure-sensitive metal salt is preferably selected from salts of copper, nickel, gold, platinum and silver. Metal salts with an oxidation state of +1 are preferred and particularly preferred are silver (I) salts, preferably a silver halide or mixture of silver halides.

The silver halide may be, for example, silver chloride, silver bromide, silver chlorobromide or silver bromoiodide. Preferably, the silver halide dispersion (or emulsion as it is called in the photographic arts) in the binder is a high contrast silver halide emulsion, which is suitable for use in the graphic arts and in manufacturing printed circuit boards (PCBs), for example. The silver halide emulsion is preferably a chlorobromide emulsion, preferably comprising at least 50 mol % silver chloride, more preferably 60-90 mol % silver chloride and most preferably 60-80 mol % silver chloride. The remainder of the silver halide is preferably substantially made up of silver bromide and more preferably comprises a small proportion (e.g. up to 1 or 2%) of silver iodide.

Where the photosensitive layers comprise an emulsion of silver halide in gelatin, the weight ratio of silver to gelatin is preferably at least 2 to 1.

Preferably, the photosensitive or pressure-sensitive material is a high metal (e.g. silver)/low binder (e.g. gelatin) material, so that after conventional development it is sufficiently conductive to enable direct electroplating of the metal pattern formed and that the degree of plating or electroplating required is less than otherwise. In this regard, a preferred ratio of binder to metal in the photosensitive or pressure-sensitive material is in the range of from 0.1 to 0.7, more preferably from 0.2 to 0.6.

The first metal is the corresponding metal of the photosensitive or pressure-sensitive metal salt and accordingly the first metal is preferably silver.

Preferably, the material is a photosensitive material.

According to the preferred embodiment, where the metal salt is a photosensitive metal salt, preferably silver halide, the metal may be sensitised to any suitable wavelength of the exposing radiation, as desired, but is preferably sensitised to light of the wavelengths emitted by solid state diode red light sources commonly used in imagesetters and photoplotters. Preferably, the metal salt dispersion is a silver halide emulsion sensitised to light in the range 600-690 nm.

The amount of sensitising dye used in a silver halide emulsion is preferably in the range of 50 to 1000 mg per mol equivalent of silver (mg/Agmol), more preferably 100 to 600 mg/Agmol and still more preferably 150 to 500 mg/Agmol. It is most preferable to incorporate the sensitising dye into the silver halide emulsion in an amount of from 300 to 500 mg/Agmol.

The emulsions employed in the materials described herein, and the addenda added thereto, the binders, etc., may be as described in Research Disclosure Item 36544, September 1994, published by Kenneth Mason Publications, Emsworth, Hants, PO10 7DQ, UK.

The photosensitive materials described herein preferably include an antihalation layer that may be on either side of the support, preferably on the opposite side of the support from the photosensitive layer. In a preferred embodiment, an antihalation dye is contained in an underlayer of a hydrophilic colloid. Suitable dyes are listed in the Research Disclosure above.

The silver halide emulsions referred to may be prepared by any common method of grain growth, preferably using a balanced double run of silver nitrate and salt solutions using a feedback system designed to maintain the silver ion concentration in the growth reactor. Dopants may be introduced uniformly from start to finish of precipitation or may be structured into regions or bands within the silver halide grains. Dopants, for example osmium dopants, ruthenium dopants, iron dopants, rhenium dopants or iridium dopants, for example cyanoruthenate dopants, may be added, preferably a combination of osmium and iridium dopants and preferably an osmium nitrosyl pentachloride (especially in combination with a red-sensitising trinuclear merocyanine dye). Such complexes may alternatively be utilised as grain surface modifiers in the manner described in U.S. Pat. No. 5,385,817. Chemical sensitisation may be carried out by any of the known methods, for example with thiosulfate or other labile sulfur compound, and with gold complexes. Preferably, the chemical sensitisation is carried out with thiosulfate and gold complexes.

The silver halide grains in the photosensitive or pressure-sensitive embodiments may be cubic, octahedral, rounded octahedral, polymorphic, tabular or thin tabular emulsion grains, preferably cubic, octahedral or tabular grains. Such silver halide grains may be regular untwinned, regular twinned, or irregular twinned with cubic or octahedral faces. The silver halide grains may also be composed of mixed halides.

In cases where the emulsion composition is a mixed halide, the minor component may be added in the crystal formation or after formation as part of the sensitisation or melting. The emulsions may be precipitated in any suitable environment such as a ripening environment, a reducing environment or an oxidising environment.

Specific references relating to the preparation of emulsions of differing halide ratios and morphologies are Evans U.S. Pat. No. 3,618,622, Atwell U.S. Pat. No. 4,269,927, Wey U.S. Pat. No. 4,414,306, Maskasky, U.S. Pat. No. 4,400,463, Maskasky U.S. Pat. No. 4,713,323, Tufano et al, U.S. Pat. No. 4,804,621, Takada et al U.S. Pat. No. 4,738,398, Nishikawa et al U.S. Pat. No. 4,952,491, Ishiguro et al U.S. Pat. No. 4,493,508, Hasebe et al U.S. Pat. No. 4,820,624, Maskasky U.S. Pat. Nos. 5,264,337 and 5,275,930, House et al U.S. Pat. No. 5,320,938 and Chen et al U.S. Pat. No. 5,550,013, Edwards et al U.S. Ser. No. 08/362,283 filed on Dec. 22, 1994 and U.S. Pat. Nos. 5,726,005 and 5,736,310.

Antifoggants and stabilisers may be added, after addition of sensitising dye to give the emulsion the desired sensitivity, if appropriate, as is known in the art. Antifoggants that may be useful include, for example, azaindenes such as tetraazaindenes, tetrazoles, benzotriazoles, imidazoles and benzimidazoles. Specific antifoggants that may be used include 5-carboxy-2-methylthio-4-hydroxy-6-methyl-1,3,3a,7-tetraazaindene, 1-(3-acetamidophenyl)-5-mercaptotetrazole, 6-nitrobenzimidazole, 2-methylbenzimidazole and benzotriazole.

Nucleators and, preferably, development boosters may be used to give ultra-high contrast, for example combinations of hydrazine nucleators such as those disclosed in U.S. Pat. No. 6,573,021, or those hydrazine nucleators disclosed in U.S. Pat. No. 5,512,415 at col. 4, line 42 to col. 7, line 26, the disclosures of which are incorporated herein by reference. Booster compounds that may be present in the photographic material (or alternatively, in the developer solution used) include amine boosters that comprise at least one secondary or tertiary amino group and have an n-octanol/water partition coefficient (log P) of at least 1, preferably at least 3. Suitable amine boosters include those described in U.S. Pat. No. 5,512,415, col. 7, line 27 to col. 8, line 16, the disclosure of which is incorporated herein by reference. Preferred boosters are bis-tertiary amines and bis-secondary amines, preferably comprising dipropylamino groups linked by a chain of hydroxypropyl units, such as those described in U.S. Pat. No. 6,573,021. Any nucleator or booster compound utilised may be incorporated into the silver halide emulsion, or alternatively may be present in a hydrophilic colloid layer, preferably adjacent the layer containing the silver halide emulsion for which the effects of the nucleator are intended. They may, however, be distributed between or among emulsion and hydrophilic colloid layers, such as undercoat layer, interlayers and overcoat layers.

A photosensitive silver halide material such as that described in U.S. Pat. No. 5,589,318 or U.S. Pat. No. 5,512,415 may be utilised.

Development of the latent image, formed from the exposure of the coated support, to form the conductive metal pattern corresponding to the desired pattern may comprise of one or more of conventional development, physical development and electrochemical development.

The latent image formed in the method of the invention is typically subjected to a conventional development step, whereby a developed image of a first metal according to the latent image is formed.

The conventional development step comprises treating the latent image with a developer composition, which may be incorporated in the coating, but requiring activation (e.g. by heating, i.e. thermal development, or changing pH), or may be added as a solution as part of a development process. The developer composition typically comprises a reducing agent, for example, capable of reducing a metal salt to the elemental metal, when catalysed by the elemental particles of the latent or germ image under the conditions of the development process.

The development step may further comprise fixing the image by treating the developed image with a fixer composition and/or a wash step, whereby the active fixer and developer components are removed and the majority of unhardened binder (e.g. gelatin) in the non-imaged areas is removed.

In order to prevent unwanted removal of the metal tracks formed, the photosensitive or pressure-sensitive layer may comprise a hardener-precursor, which hardens upon reaction, for example, with oxidised developer or other side-product of the development process, thereby hardening the binder material in only those areas where metal tracks are formed and thus enabling a selective wash-off process.

In a preferred embodiment of the process of the invention, the developed element is subjected to a hot-fix step in order to remove unwanted residual gelatin from non-imaged areas thereof. Preferably, according to this embodiment, the latent image is formed on an element comprising a silver halide emulsion in gelatin as binder. After development, the developed element is immersed in a fix solution, such as the Kodak RA 3000™ fix, at an elevated temperature (e.g. at least 30° C., preferably 35-45° C.) which causes softening of the gelatin in unexposed regions and melting, dissolution or delamination thereof to leave only the exposed silver tracks as a relief image. The hot-fix is more efficient and also rids the developed element of residual undeveloped silver halide grains which otherwise are at risk of being plated in subsequent steps and/or obscuring the view through the element. The gelatin in and beneath the tracks formed is unaffected by the hot-fix/wash since it is less accessible, is held together by the tracks themselves and is hardened somewhat by side-products of the development step.

In a preferred embodiment, where the metal salt is a photosensitive or pressure-sensitive silver halide, it may be processed following exposure to form a visible image by associating the silver halide with an aqueous alkaline medium in the presence of a developing agent contained in the medium or in the material itself. The material may be processed in conventional developers to obtain very high contrast images. When the material contains an incorporated developing agent, it can be processed in the presence of an activator, which may be identical to the developer in composition, but lacking a developing agent.

The developers are typically aqueous solutions, although organic solvents, such as diethylene glycol, can also be included to facilitate the solution of organic components. The developers contain one or a combination of conventional developing agents, such as for example, a polyhydroxybenzene such as dihydroxybenzene, aminophenol, a paraphenylenediamine, ascorbic acid, erythorbic acid and derivatives thereof, pyrazolidone, pyrazolone, pyrimidine, dithionite and hydroxylamine.

It is preferred to employ hydroquinone and 3-pyrazolidone developing agents in combination or an ascorbic acid-based system in the development of silver halide latent images. An auxiliary developing agent exhibiting super-additive properties may also be used. The pH of the developers can be adjusted with alkali metal hydroxides and carbonates, borax and other basic salts. It is a particular advantage that the use of nucleators as described herein reduces the sensitivity of photosensitive material to changes in this developer pH.

To reduce swelling of a hydrophilic binder (e.g. gelatin) during development, compounds such as sodium sulfate may be incorporated into the developer. Chelating and sequestering agents, such as ethylenediamine tetraacetic acid or its sodium salt, can be present. Generally any conventional developer can be used in the practice of this invention. Specific illustrative photographic developers are disclosed in the Handbook of Chemistry and Physics, 36^{th} Edition, under the title “Photographic Formulae” at page 30001 et seq. and in “processing Chemicals and Formulas”, 6^{th} Edition, published by Eastman Kodak Company (1963).

The development step, after a conventional development, typically comprises a physical development step and/or (preferably) an electrochemical development step.

By physical development (or electroless plating), it is meant that the latent image or the metal image formed by conventional development is treated with a solution of a metal salt or complex of the same or different metal as that formed by conventional development of the latent image. The physical development composition may further comprise a reducing agent to enable direct physical development of the latent image. However, it is preferred to carry out a conventional development step prior to any plating step.

By subjecting the developed element to electrochemical development (or electroplating), optionally after electroless plating, it is meant that a conductive metal image formed by conventional development and/or physical development has a voltage applied across it in the presence of a plating solution comprising a salt or complex of a plating metal, which may be the same or different from that of the metal image to be plated, whereby the conductive metal image is made more conductive. Suitable metals for use as the second metal (through electroless or electroplating) include, for example, copper, lead, nickel, chromium, gold and silver, preferably copper or silver and most preferably silver.

Preferably, the plating solution used in the physical development process (i.e. electroless plating) comprises ions of the plating metal in an amount of from 0.01 M to 2 M, more preferably 0.02 M to 0.1 M.

Where the development of the exposed photosensitive element comprises a conventional development step and an electrochemical development step (i.e. direct electroplating of a developed image), it is necessary that the image formed by conventional development is sufficiently conductive when a voltage is applied across it. In this case, it is preferable to use the electroplating technique described in our U.S. patent application Ser. No. 11/400,928 entitled, “Method of Forming Conductive Tracks”, the contents of which are incorporated herein by reference.

The electroplating step of the process is achieved by providing a plating solution in contact with the developed metal image whilst applying a voltage across the photographically generated pattern through the solution, by making the photographically generated pattern the negatively charged electrode (referred to as the cathode in electrochemistry) in an electrochemical cell. The plating solution utilised according to the process of the invention may be, for example, a solution of a silver thiosulfate complex, e.g. Na₃Ag(S₂O₃)₂, where silver is the plating metal (the second metal), a solution of copper sulfate optionally with or without a polyethylene glycol PEG 200 where copper is the plating metal, nickel sulfate, i.e. NiSO₃, in the presence of boric acid where nickel is the plating metal, or zinc sulfate, ZnSO₄, where zinc is the plating metal. Preferably the plating solution has an equivalent concentration of the plating metal of from 0.01 to 2 molar, more preferably 0.03 to 0.5 molar and still more preferably 0.05 to 0.2 molar. Boric acid to control pH and/or PEG as a throwing agent may optionally be added to any of the plating solutions utilised.

As mentioned above, silver is preferably the plating metal, so a solution of a silver salt or complex is preferably used. The silver salt is preferably a silver thiosulfate complex, e.g. Na₃Ag(S₂O₃)₂, and can be formed by making a solution of silver chloride, sodium sulfite and ammonium thiosulfate. Preferably, the silver plating solution has an equivalent concentration of silver of from 0.01 to 2 molar, more preferably 0.03 to 0.5 molar and still more preferably 0.05 to 0.2 molar. The low equivalent concentration of silver in the plating solution enables the plating process to be controlled, allowing even plating across the patterned conductor and minimising the build-up of plating metal close to the electronic contacts.

The formulation of metal salts for use in the plating solution may be adapted from any suitable plating solution formulation, a useful source of known plating solution formulations including “Modern Electroplating” 4^{th} Edn, Ed. M. Schlesinger, M. Pacinovic, published by Wiley.

In a preferred embodiment of the process of the invention, the binder in the photosensitive or pressure-sensitive material is susceptible to decomposition and/or dissolution upon treatment with an enzyme solution and the process further comprises treating the developed element, prior to and/or during the plating step(s), with an enzyme capable of decomposing and/or dissolving the binder. The enzyme treatment step is preferably carried out in the manner described in our UK patent application No. 0518613.5 of even date, entitled “Method of Forming Conductive Tracks” (our docket no.: 89168 GB), the contents of which are incorporated herein by reference.

The enzyme used is selected according to the binder in the element in which the conductive tracks are formed and may be selected depending upon the activity of a certain enzyme with the binder being used. The enzyme is typically used as a solution in which the developed metal image is immersed (or may be provided as a thin process coating). Another consideration in the choice of enzyme is the pH at which the enzyme works. The choice of enzyme may therefore be affected by the pH of the plating solution or of the wash/fix solution, especially if the enzyme treatment step is to be carried out within another step.

The amount of enzyme and the concentration of the solution used depends upon several factors, such as the activity of the enzyme on the binder used, whether or not the binder has been hardened or cross-linked, the pH of the enzyme solution and the duration of treatment. The amount of enzyme used and the duration of treatment may be altered as appropriate to maximise the effect of the residual binder removal process, whilst ensuring the track pattern is not disrupted (since it is bound to the support by the binder composition itself). Typically, for use with an exposed and developed high silver/low gelatin element, an enzyme solution (whether as part of a plating solution or not) comprises from 0.5 to 20 g/l of enzyme, preferably 1 to 10 g/l, and the duration of treatment is from 10 seconds to 10 minutes, preferably 30 seconds to 3 minutes. Typically, the enzyme treatment will be carried out at 40° C. or below.

In another embodiment, the developed element may be subjected to ultrasonic agitation during the electroless and/or electroplating step(s) to provide conductive tracks with improved resolution in a shorter time, as described in our UK patent application No. 0518613.5 of even date entitled “Method of Forming Conductive Tracks” (our docket no. 89392 GB), the disclosure of which is incorporated herein by reference.

To subject the developed element to ultrasonic agitation during the plating step(s), the plating step may be carried out in an ultrasonic bath, for example, or an ultrasonic probe placed in the plating solution, or alternatively ultrasonic pads attached directly to the developed element itself (e.g. to the reverse side of the element). In any case, any suitable method of subjecting the developed element to ultrasonic waves during plating is considered within the scope of the invention. The frequency of ultrasound used typically depends upon the available transducers, which are usually in the range 30-100 kHz and normally about 60 kHz.

According to an alternative embodiment where the latent image formed is heat developed to generate tracks according to the desired track pattern, the photosensitive or pressure-sensitive material comprises a photosensitive or pressure-sensitive silver halide material and a secondary source of reducible silver ions in catalytic proximity thereto.

Preferably, according to this embodiment of the invention, the silver halide material comprises that described generally above or more particularly one or more silver halides (often referred to as photocatalysts in the photo-thermographic (PTG) imaging arts) such as silver bromide, silver iodide, silver chloride, silver bromoiodide, silver chlorobromoiodide, silver chlorobromide and others readily apparent to one skilled in the art. Silver bromide and silver bromoiodide are more preferred, the latter silver halide including up to 10 mol % silver iodide.

The silver halide grains preferably utilised in this embodiment may have a uniform ratio of halide throughout, may have a graded halide content with a continuously varying ratio of, for example, silver bromide and silver iodide, or they may be of the core-shell type having a core of one halide ratio and a shell of another halide ratio. Core-shell silver halide grains useful in PTG materials and methods of preparing these materials are described, for example in U.S. Pat. No. 5,382,504, which disclosure is incorporated herein by reference, as are the relevant disclosures of U.S. Pat. No. 5,434,043, U.S. Pat. No. 5,939,249 and EP-A-0627660, which describe iridium and/or copper doped core-shell and non-core shell grains.

The secondary source of reducible silver ions may be any silver ion source suitable for use in PTG imaging and is preferably a non-photosensitive silver salt that forms a silver image when heated to 50° C. or higher in the presence of an exposed photosensitive or pressure-sensitive silver halide material and a developer composition. The secondary silver ion source may be, for example, one or more of silver benzotriazoles, silver oxalates, silver acetates and silver carboxylates, such as silver behenates, or any silver ion source selected from those described in EP-A-1191394 at page 23 line 17 to page 24, line 14, the disclosure of which is incorporated herein by reference. Preferably, the secondary silver ion source is a silver benzotriazole, suitable such benzotriazoles being disclosed in U.S. Pat. No. 3,832,186, the disclosure of which is incorporated herein by reference, or a silver soap, such a silver behenate, having a formula [Ag(CO₂CₓH₂ₓ₋₁)]₂, preferably where x=18-22.

In a heat developable element that may be used according to this embodiment, it is preferred that the photosensitive or pressure-sensitive silver halide be present in an amount of from 0.005 to 0.5 mol per mol of secondary silver source, more preferably 0.01 to 0.15 mol and still more preferably 0.03 to 0.12 mol. It is also preferable that the photosensitive or pressure-sensitive silver halide be present in an amount of 0.5 to 15% by weight of the emulsion layer in which it is contained and more preferably from 1 to 10% by weight.

In this embodiment in which the latent image is developed through a heat development step, the secondary silver ion source and the silver halide material must be in catalytic proximity (i.e. in reactive association).

The emulsion of the silver halide material and secondary silver ion source may be prepared by any suitable method for use in PTG imaging. It is preferred that an ex situ method is used whereby the photosensitive or pressure-sensitive silver halide grains are preformed then added to and physically mixed with the silver ion source, or alternatively, the silver ion source is formed in the presence of ex situ prepared silver halide such as by co-precipitation of the silver ion source in the presence of silver halide to provide a more intimate mixture. The preformed silver halide emulsions or dispersions utilised in this method may be prepared by aqueous or organic processes and can be unwashed or washed to remove soluble salts. Alternatively, an in situ process in which a halide-containing compound is added to an organic silver salt to partially convert the silver of the organic silver salt to silver halide may be effective. The halogen-containing compound may be inorganic, such as zinc bromide or lithium bromide or organic, such as N-bromosuccinimide. Additional methods of preparing the silver halide and organic silver salts and manners of blending them are described, for example, in Research Disclosure, June 1978, Item No. 17029, U.S. Pat. No. 3,700,458 and U.S. Pat. No. 4,076,539. The photosensitive or pressure-sensitive silver halide material used according to this embodiment may be chemically sensitised and spectrally sensitised, if appropriate, by any suitable method known in the PTG art.

The developer composition, which may be incorporated into the coated support, may be any suitable developer for reducing the source of silver ions to metallic silver in PTG imaging systems. Suitable such developers include those described in EP-A-1191394 at page 24, line 18 to page 24, line 51, which disclosure is incorporated herein by reference. Particularly preferred developer compositions are the bisphenol class of PTG developers.

A development activator, also known as an alkali-release agent, base-release agent or an activator precursor, may be useful in the development of latent images according to the present embodiment. A development activator is an agent or compound which aids the developing agent at processing temperatures to develop a latent image in the imaging material. Useful development activators or activator precursors are described, for example, in Belgian Pat. No. 709, 967 published Feb. 29, 1968, and Research Disclosure, Volume 155, March 1977, Item 15567. Examples of useful activator precursors include guanidinium compounds such as guanidinium trichloroacetate, diguanidinium glutarate, succinate, malonate and the like; quaternary ammonium malonates; amino acids, such as 6-amino-caproic acid and glycine; and 2-carboxycarboxamide activator precursors.

Other addenda that may be incorporated into the coated support to be used in the PTG system according to this embodiment include, for example, stabilisers, toners, anti-foggants, contrast-enhancers, development-accelerators, post-processing stabilisers or stabiliser precursors and other image-modifying agents, as would be readily apparent to the person skilled in the art. Heat-transfer agents may also be incorporated.

The steps of electroless plating and electroplating are largely as described above.

The photosensitive or pressure-sensitive element used in this invention may have photosensitive or pressure-sensitive material coated onto each side of a support substrate. In this case, the element may be a photosensitive element such as that described in patent application No. PCT/GB2006/001099, the disclosure of which is incorporated herein by reference.

In particular, according to this embodiment, the photosensitive element comprises a first photosensitive layer sensitive to radiation of a first spectral region coated on one side of the support and a second photosensitive layer sensitive to radiation of a second spectral region coated on the other side of the support, whereby upon exposure to radiation of respective first and second spectral regions according to a desired pattern and development of the exposed photosensitive layers, the first and second photosensitive layers form developed metal images having a pattern of conductive tracks corresponding to the desired pattern. The first and second spectral regions may be the same, but are preferably different, or at least have different wavelengths of maximum absorption and little overlap. Where the support is transparent, the photosensitive layers may be imaged from the same side of the element. Chemical and spectral sensitisation and the make-up of the photosensitive layers are as described above.

Forming the dissipative metal pattern of conductive tracks of the heating element on only one side of the support is considered adequate for most applications and is preferred in view of the simpler process and materials.

Where the latent image is formed upon the coated support by applying pressure thereto according to a pattern, the degree of pressure to be applied is commensurate with the pressure-sensitivity of the coated support, which could depend upon the precise nature of the coated support and would be readily appreciated by the skilled person in the art. The method of applying pressure to generate a latent image is any suitable method by which a desired image can be applied, using any suitable pressurising device. For example, the latent image may be formed by applying pressure using a stylus (especially a high resolution stylus) or scalpel, an engraved stamp engraved according to the desired track pattern or a roller carrying a relief pattern according to the desired track pattern such that latent images can be formed rapidly on a sequence of coated supports, especially flexible coated supports. Where the desired track pattern is a random conductive track pattern, the latent image may be formed by any suitable means of generating a random pattern such as by rubbing the surface of the coated support with steel wool or (plastic) scouring pad or equivalent.

The resolution of the conductive tracks formed depends primarily on the resolution of the photo-imaging or pressurising device, since the process of the invention provides that, subject to this limitation, very high resolution track and gap widths are achievable (e.g. upwards of 0.1 μm). For many applications, it is preferred to form high resolution conductive tracks. Preferably, therefore, the conductive tracks formed have a line width of 50 μm or less, more preferably 25 μm or less, still more preferably 20 μm or less or 15 μm or less, more preferably still 10 μm or less. Line widths of 1 or 2 μm may even be formed by this method.

Preferably the heating element has an optical transmission of at least 80%, more preferably at least 90%.

The track pattern generated to form the heating element according to this invention may be practically any desired pattern. Because the pattern is generated image-wise by exposure to radiation or application of pressure and because the method is capable of generating the conductive patterns at high resolution, the variety of different track patterns, track widths, gap widths and arrangements is huge and varied patterns can easily be adopted.

Accordingly, the track pattern may comprise, for example, an array of straight lines, curved lines, wavy or undulating lines or crimped or zig-zagged lines, which connect one connection point (to the voltage supply) to another connection point to an opposing charge (typically bus-bar arrangements). The gaps between such lines may be of constant size or may vary across the breadth of the heating element.

The arrangement may be substantially of non-intersectional lines, e.g. a substantially parallel arrangement of lines (e.g. bus-bar to bus-bar connections), a fan arrangement (one or more similarly charged connection points linked to a bus-bar having an opposing charge) or a point to point arrangement (e.g. several points of one charge linked to several points of the opposite charge), which depends upon the size and shape of the heating element desired (which normally corresponds to the size and shape of, for example, the windscreen to be heated).

However, preferably the track pattern is generated in a mesh arrangement.

By mesh, it is meant a track pattern where multiple internal connections (or track intersections) occur (i.e. in the area separating the connection points) between tracks or lines linking the connection points where the tracks cross other tracks, whereby the mesh tends to have an isotropic surface resistivity, as compared with a substantially parallel arrangement of lines or conductive wires which tends to have an anisotropic surface resistivity (tending to be one-dimensional).

Particular advantages of a mesh pattern include the capability of providing an isotropic surface resistivity and consequently a very even distribution of heat. It also has the advantage that where a burn-out may occur or a track connection fails, the heating effect is largely maintained as there are several other routes through the mesh by which the heating can be effected. It is also effective in preventing hot-spots occurring.

The mesh may be a regular pattern, for example with a mesh diameter of 2 mm or less, or an irregular or random pattern. For example, a random pattern could be generated by pressure exposure of a pressure-sensitive element using a steel wool or plastic equivalent or firm brush.

Preferably, the mesh is formed of a regular pattern. Such a regular mesh may comprise, for example, triangular, square or diamond, rectangular or hexagonal unit cells.

The size of the mesh may be constant or may vary across the breadth of the element (e.g. smaller mesh in areas where visibility is more crucial).

The mesh sizes, line widths (and track conductivity) useful in any particular embodiment of this invention depend on several factors. The main factors are the size of the voltage source (for many automobile applications the power source is usually a 12V source), the desired dissipative power output (e.g. for a car windscreen heater, at least 4.5 W/dm² is suitable), the desired transparency (at least 80%, preferably at least 90%) and the size and shape of the screen.

The various embodiments described herein will tend to describe the mesh sizes, line widths and conductivities/surface resistivities (sheet resistances) suitable for use with a 12V power supply, a dissipative heat output of at least 4.5 W/dm², an optical transmission of at least 80% and an element size of up to 0.5 m² (i.e. suitable for use as car windscreen elements). It would be understood by the skilled person that the preferred line widths, gaps and conductivities for elements where these factors are different could be readily determined and are included within the scope of this invention.

Preferably, in the embodiment of the invention utilising a mesh pattern, especially a regular mesh pattern, the mesh size is any suitable size according to the desired utility and preferably is of a mesh diameter of 5 mm or less, more preferably 2 mm or less and still more preferably 1 mm or less. Still smaller mesh sizes are achievable using the method of the invention, e.g. 0.1 to 0.5 mm and may find utility in certain applications, such as in visors or other optical devices located relatively close to the observer.

Line widths useful in the heating element of the invention again depend on various factors, including the desired optical transmission of the heating element, the mesh size/gap width and the conductivity. In any case, it is preferred that the lines are of a width 100 μm or less, more preferably 50 μm or less and most preferably 25 μm or less. For some applications and in some circumstances, it is preferred to have significantly smaller line widths, such as 20 μm, 15 μm or even 10 μm.

The heat elements formed by the method of the invention preferably provide a uniform (and in any case, at least a desired minimum) dissipation of heat over the area of the element (and, therefore any object, such as an automotive windscreen to which it is applied). This level is well known for an automotive windscreen, used as an industry standard and generally accepted to be 4.5 W/dm². The heating element of the invention, when connected to a 12V supply, is capable of providing at least 4.5 W/dm² of power output to an area of up to 0.5 m².

The key electrical characteristic of the conducting meshes used here (as a preferred embodiment of the invention) is surface resistivity in ohms/square, whilst the key optical characteristic is transmission throughout the visible spectrum. Essentially, this is the proportion of the surface area of the mesh not occupied by the non-transparent conductor. The dimension of crucial visual access will typically be 80×40 cm or less, and this dimension will be used in the following discussion to exemplify design considerations.

To deliver 4.5 W/dm² over a rectangular area 80×40 cm, in the simplest practical embodiment, two highly conductive bus-bars are placed as contacts along each edge of the two longer sides, i.e. the 80 cm sides of area indicated above. To dissipate 4.5 W/dm² over the full 80×40 cm area requires a total dissipation of 142 W. For a 12 V supply, this amounts to a total resistive load of slightly more than 1 ohm. Typically, the 80 cm×40 cm area comprises two 40×40 cm squares being supplied as parallel loads. Thus, in this typical example, without more complicated bus-bar routing, the mesh surface resistance required would be 2 ohms/square. This value has been demonstrated by the methods of producing a mesh described herein.

The method described herein for producing silver meshes image-wise can deliver unit cells of different shapes (for example, triangular, square, diamond-like or hexagonal). The meshes made according to the preferred embodiments of the invention typically have track widths of 10 μm or greater, with typical solid metal surface resistance values of 0.1 Ω/square or lower. Adopting a 4-sided (square) unit cell as an example, the relation between surface resistivity of the mesh (Rₘₑₛₕ) as a function of the optical transmission (T) and surface resistivity of continuous metal surface (R_{solid}) of the same thickness becomes:

Rₘₑₛₕ=R_{solid}{[1/(1−√T)]−√T}

TABLE 1 shows some representative values of useful and achievable surface resistivity and optical transmission based on an R_{solid} value of 0.1 Ω/square.

TABLE 1
Calculated values of surface resistivity and optical transmission
for a square mesh, with R_{solid} = 0.1 Ω/square.

| Track width | Mesh pitch | Surface resistivity | Optical |
|---|---|---|---|
| (μm) | (μm) | (ohms/square) | transmission (%) |
| 10 | 100 | 0.91 | 81 |
| 10 | 200 | 1.91 | 90 |
| 10 | 500 | 4.90 | 96 |
| 20 | 200 | 0.91 | 81 |
| 20 | 500 | 2.40 | 92 |
| 20 | 1000 | 4.90 | 96 |
| 50 | 500 | 0.91 | 81 |
| 50 | 1000 | 1.91 | 90 |
| 50 | 2000 | 3.90 | 95 |

In the design example above, 2 Ω/square is achieved when the wire thickness is 1/20^{th} of the mesh pitch, with an optical transmission of no less than 90%. The absolute value of the pitch can thus be chosen to be appropriate for the specific optical siting of the window/windscreen with respect to the observer.

A desirable mesh size/line width combination may be, for example, a mesh size of diameter 1 mm with a line width of 50 μm or less (which would enable about 90% transmission for a square mesh), or even 25 μm or less (which would enable about 95% transmission).

As mentioned above, the line widths and gap widths/mesh sizes utilised depend on other factors, such as the power dissipation required in any particular embodiment, the size of the element and the surface resistivity of the element. For most applications, it is desirable that the element has a conductivity of 50 ohms/square or less, preferably at least 1 ohm/square. A conductivity of about 50 ohms/square may be useful for smaller applications, such as wing-mirror or rear-view mirror or portable visor. For most applications, such as a car windscreen heater, a surface resistivity of 10 ohms/square or less is preferable, and more preferably from 2 to 2.5 ohms/square. Still lower surface resistivities may be desirable for very large applications.

The method of the invention is capable of providing a metal pattern with such surface resistivities, e.g. of 10 ohms/square or less, typically about 2 ohms/square, with an optical transmission of at least 80%, generally at least 90%. Accordingly, the method of the invention can provide heating elements useful for most applications and in particular, for heating vehicle windscreens, in a very effective and efficient manner. The method is also exceedingly versatile being capable of providing practically any track pattern in any desired element shape and on a flexible substrate, without major alterations in the manufacturing process.

The conductive track pattern may be connected to its power supply via two or more connection points, such as bus-bars. The bus-bars may be formed as conductive metal strips, such as those described in U.S. Pat. No. 6,185,812, or may be formed using a current-carrying mesh (e.g. U.S. Pat. No. 4,361,751), or may be printed onto the support substrate using conductive ink. Alternatively, and preferably, with the heating elements of the present invention, bus-bars are formed integrally with the power dissipative metal pattern of the heating element by imaging (via radiation exposure or pressure exposure as appropriate) onto the same photosensitive or pressure-sensitive element as the conductive pattern of the heating element. In this way, the bus-bars may be formed, for example, as solid current-carrying bus bars or thick current-carrying meshes (of much greater line width and mesh pitch to that of the power dissipative heat element).

In a particular application of the invention, the heating element is used to provide heating to a vehicle windscreen, especially car windscreens. In this application, the heating elements of the invention may be incorporated into the windscreen, for example, by laminating or applying the element onto the inside or outside of the windscreens, optionally such that it can be removed and replaced if necessary, or by laminating the element between two plies of transparent glazing material used to form the windscreen. Methods of manufacturing windscreens using two or more plies of glazing material are well known and described in the patent literature, such as in U.S. Pat. No. 6,185,812 and others and may be adapted to incorporate heating elements made in accordance with the present invention.

Accordingly, in another aspect of the invention, there is provided an electrically heated window laminated from at least two plies of transparent glazing material and at least one ply of interlayer material extending between the plies of glazing material, the window comprising an electrically resistant power dissipative heating means extending between the plies of glazing material and an elongate electrical connection means extending from the heating means past the peripheral edge of the window and terminating outside the window, wherein the electrically resistant power dissipative heating means is provided by a heating element described herein. Preferably, the interlayer material is the heating element formed on a flexible transparent support.

This invention will now be described in more detail, without limitation, with reference to the following Examples and Figures.

### EXAMPLES

### Example 1

A photosensitive film was prepared which on the backside contained an antihalation layer with protective topcoat and on the front side an emulsion layer sensitive to red light, with a protective topcoat.

### The Antihalation Layer:

A dispersion was prepared by the addition of 13.3 kg water to 705 g lime processed ossein (LPO) gelatin. After soaking, the gelatin was dissolved at 49° C. and the pH was adjusted using dilute sulfuric acid to 5.3. 239 g 2-(3-acetyl-4-(5-(3-acetyl-1-(2,5-disulfophenyl)-1,5-dihydro-5-oxo-4H-pyrazol-4-ylidene)-1,3-pentadienyl)-5-hydroxy-1H-pyrazol-1-yl)-1,4-benzenedisulfonic acid, pentasodium salt [CAS No 127093-24-7] as a 10% aqueous dispersion was added, followed by 188 g 4-(4,5-dihydro-4-(5-(5-hydroxy-3-methyl-1-(4-sulfophenyl)-1H-pyrazol-4-yl)-2,4-pentadienylidene)-3-methyl-5-oxo-11H-pyrazol-1-yl)-benzenesulfonic acid [CAS No 27969-56-8] as a 13% aqueous dispersion, followed by 1.1 kg Ludox™ AM, a 30% silica dispersion available from W. R. Grace, followed by 63.4 g glycerol [CAS No 56-81-5] as a 63% aqueous solution, followed by 70.5 g polystyrene sulfonate [CAS No 25704-18-1] as 10% aqueous solution. The whole was made up to 15.75 kg.

### The Antihalation Layer Protective Topcoat:

A dispersion was prepared by the addition of 3.8 kg water to 519 g LPO gelatin and, after soaking, the gelatin was dissolved at 49° C. 465 g of an 8% aqueous dispersion of polymethacrylate matte beads (4-10 μm) was added, followed by 0.5 kg octamethylcyclotetrasiloxane [CAS No 556-67-2] as a 9.3% aqueous dispersion, followed by surfactants to ensure a good coating quality, the pH adjusted to 5.3 and the whole made up to 6 kg.

The two layers were then co-coated such that the gelatin in the antihalation layer was at 2 g/m² and the protective topcoat at 0.488 g/m² onto 7 thou clear subbed Estar™ polyestar base available from Kodak™.

Red-Sensitive layer:

A high contrast emulsion was used in this layer consisting of a sulfur- and gold-sensitised 0.2 μm cubic silver bromochloride (AgBr_{0.3}Cl_{0.7}) in a binder system. The silver halide was sensitised to red light using potassium iodide and a sensitising dye: 5-[3-(carboxymethyl)-5-[2-methyl-1-[(3-methyl-2(3H)-benzothiazolylidene)methyl]propylidene]-4-oxo-2-thiazolidinylidene]-4-oxo-2-thioxo-3-thiazolidineacetic acid [CAS No 253869-55-5]

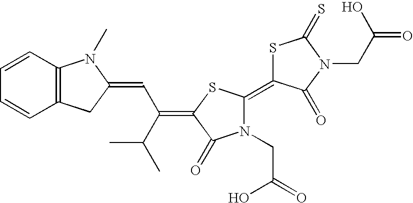

The silver laydown was 3.6 g/m². The binder system consisted of LPO gelatin at 1.6 g/m². The emulsion was protected against fogging by the use of a tetraazaindene: 7-hydroxy-5-methyl-2-(methylthio)-(1,2,4)triazolo(1,5-a) pyrimidine-6-carboxylic acid, a phenylmercaptotetrazole: N-(3-(2,5-dihydro-5-thioxo-1H-tetrazol-1-yl)phenyl)-acetamide, and 2,3-dihydro-2-thioxo-4-thiazole-acetic acid. The viscosity was adjusted to ˜6 cP by the use of polystyrene sulfonic acid at a pH of 5.1.

### Emulsion Topcoat:

A solution was prepared by the addition of 1528 g water to 64.5 g of LPO gelatin. After soaking, the gelatin was dissolved at 49° C. 390 g of a 4.7% aqueous solution of acidified hydroquinone was added, followed by 41 g of a dispersion of DC-200™ [CAS No 63148-62-9] in gelatin such that this polydimethylsiloxane (available from Dow Chemical) was at a coverage of 45 mg/m². 113 g of a 20% aqueous solution of Tiron™ [CAS No 149-45-1] was added, followed by 137 g of a 10% aqueous solution of a booster (contrast-promoting agent)

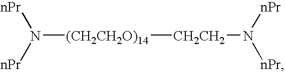

followed by a small amount of surfactant and polystyrene sulfonic acid to aid coating. The pH was adjusted to 5.1. The gelatin laydown for this layer was 0.3 g/m².

The red-sensitive layer and topcoat were co-coated onto the previously prepared substrate containing an antihalation layer.

Each film was then exposed on an Orbotech™ 7008m laser plotter with a mesh pattern, in this example essentially a honeycomb arrangement with a connector pad at each end. The mesh consisted of fine wires separated by a distance of 1732 μm.

The film was developed in a tanning developer which consisted of solutions A and B which were mixed in a 1:1 ratio (i.e. 100 ml+100 ml) just prior to use.

Solution A

| | | |
|---|---|---|
| Pyrogallol | 10 | g |
| Sodium sulfite | 0.5 | g |
| Potassium bromide | 0.5 | g |
| Water to | 500 | ml |

Solution B

| | | |
|---|---|---|
| Potassium carbonate | 50 | g |
| Water to | 500 | ml |

Development was for about 7 min. at room temperature (21° C.). The oxidation products from the development hardened the gelatin in the exposed areas.

The film was then given a ‘hot-fix’. The film was immersed in Kodak RA 3000™ fix solution at 40° C. for 10 min. The gelatin in the unexposed region became soft and either melted, dissolved or simply delaminated, leaving only the exposed silver as a relief image. The ‘hot-fix’ was not only more efficient than a cold or warm water wash, but also rid the image of a few residual undeveloped silver halide grains. These grains could otherwise have become silver in the subsequent plating bath and have limited the resolution of the final track.

To ensure that all unwanted gelatin was removed, the relief image was given a wash with a dilute enzyme bath. The enzyme bath was prepared by taking 6.3 g of Takamine powder dissolved in 1.3 l demineralised water. After 1 h of stirring the material was filtered through a 3.0 μm filter, then through a 0.45 μm filter. The final bath was made up of 3 ml concentrate diluted to 600 g with demineralised water. The enzymolysis took about 1 min. at room temperature. The film was then rinsed in cold water for 5 min. and then dried.

The film was then immersed in an electroless silver plating bath at room temperature for 10 min. The composition of the bath comprised Part A and Part B which were mixed just prior to use.

Part A

| | | |
|---|---|---|
| Ferric nitrate nonahydrate | 20 | g |
| Citric acid | 10.5 | g |
| Water to | 250 | g |
| warm to >25° C. | | |
| Ammonium ferrous sulfate•12H₂O | 39.2 | g |
| Water to | 367.5 | g |
| DDA** 10% | 2.5 | g |
| Lissapol ™ 1 ml in 100 ml | 2.5 | g |
| **DDA 10% | | |
| Water | 90 | ml |
| Dodecylamine | 7.5 | g |
| Acetic acid glacial | 2.5 | g |

Part B

| | | |
|---|---|---|
| Silver nitrate | 5 | g |
| Water to | 125 | g |

The optical transmission and sheet resistivity of the mesh was then measured and is shown in TABLE 2.

TABLE 2

| Centre point to centre | | Sheet | |
|---|---|---|---|
| point separation of | Wire Thickness/ | Resistance/ | Optical |
| parallel wires/μm | μm | Ω/square | Transmission |
| 1732 | <25 | 7.8 | 92% |

This method was capable of producing extremely fine conductive wires with an optical transmission of greater than 90%. Such devices can be used as heaters. Competing technologies such as silk-screen printing cannot achieve such fine lines and other techniques cannot achieve the conductivity and optical transmission.

### Example 2

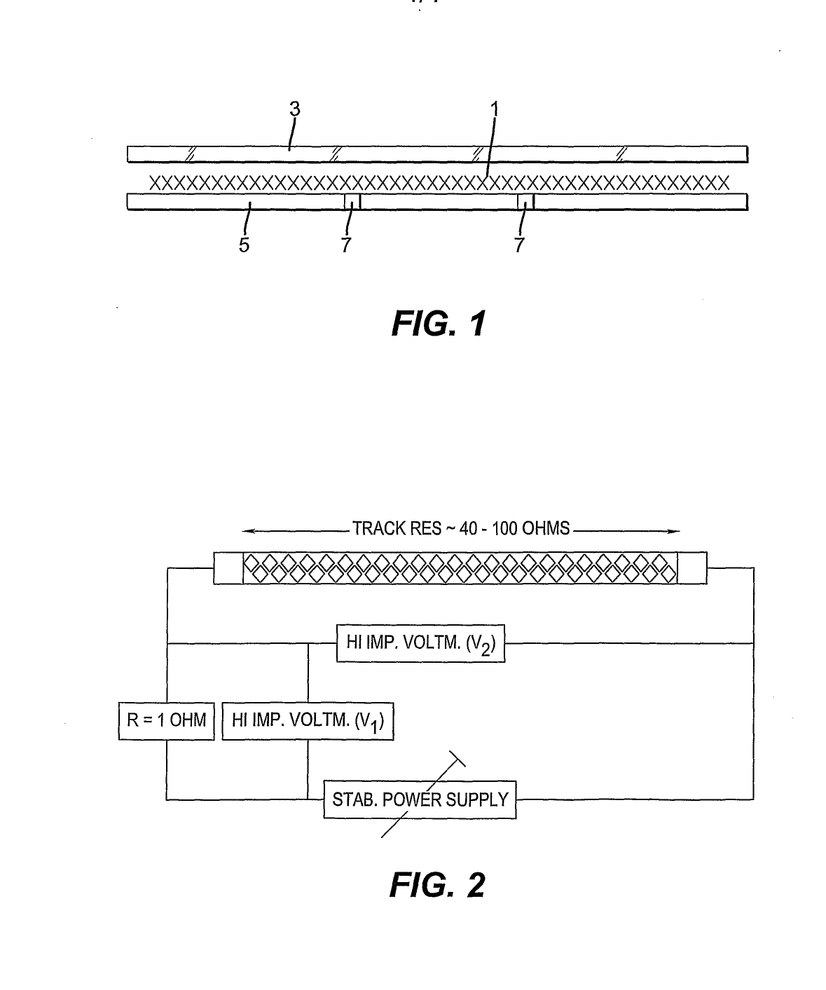

In this example, the sample was a honeycomb mesh of 6.8 cm×0.5 cm, formed by the method of Example 1. A surround area on each side to a depth of 0.15 cm made the total area 6.4 cm². The overall sheet resistivity of this sample was measured at 7.83 ohms/square and the mesh area had an optical transmission of 92%, including the base and background photographic fog. As shown in FIG. 1, the mesh on its support (1) was clamped between a microscope slide (3) (in contact with the mesh side) and an aluminium base (5) containing two temperature sensors (7) (in contact with the bare support). One or two drops of silicone oil were used to provide good thermal contact between the flexible support and the glass and aluminium surfaces.

A circuit, as shown in FIG. 2, was used to monitor the performance of the mesh as a heating element, by determination of the temperature and conductivity profiles and the breakdown power.

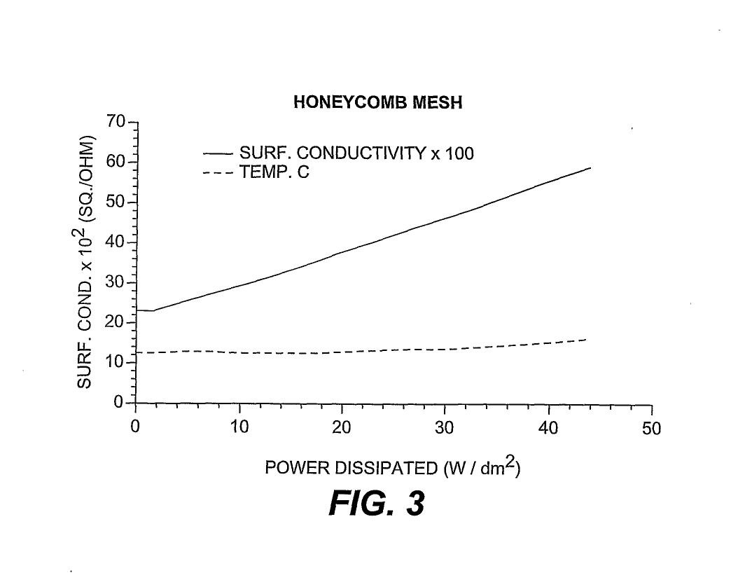

For car windscreen applications it is well known that heat dissipation should reach ˜5 W/dm². Therefore the median power required for the sample area=(6.4/100)×5˜0.32 W. Measurements (see TABLE 3 below) were made in constant current mode, each point being determined at the end of 60 s duration. Conductivity (=V₁/V₂) vs Power (=V₁·V₂) was then plotted until breakdown (see graph in FIG. 3), which occurred at 44 W/dm² at a temperature of 59° C. In an additional test, the heater was maintained at a dissipation rate of 10 W/dm² for a continuous period of 2 h without deterioration of physical or electrical characteristics.

TABLE 3

| Power | | | |
|---|---|---|---|
| dissipation | Res. (ohms/ | Conductivity | Temperature |
| (W/dm²) | square) | (square/ohms) | (° C.) |
| 0.063 | 7.83 | 0.128 | 23.1 |
| 0.26 | 8.12 | 0.123 | 23 |
| 1.585 | 7.93 | 0.126 | 23.1 |
| 6.306 | 7.88 | 0.127 | 26.8 |
| 14.391 | 8 | 0.125 | 32.8 |
| 23.976 | 7.49 | 0.133 | 41.3 |
| 34.412 | 6.88 | 0.145 | 50.3 |
| 43.835 | 6.09 | 0.164 | 59 |

### Example 3

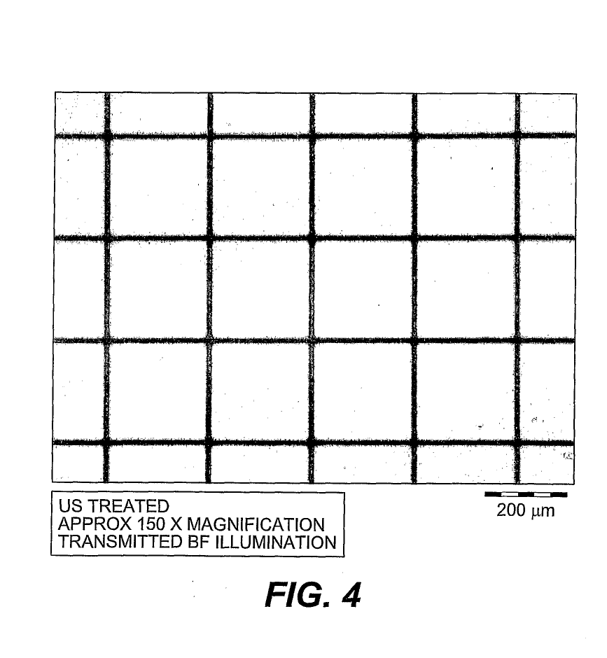

Two meshes were produced by the method of Example 1 with nominal 10 μm lines spaced 250 μm apart. Both were grown for the same length of time (1 h) in a plating bath but Sample 1 was ultrasonically treated. The mesh of Sample 1 (see FIG. 4) had a sheet resistance of 5.5 Ω/square. The tracks had a sheet resistance of 0.14 Ω/square and the transparency of the mesh was >85%.

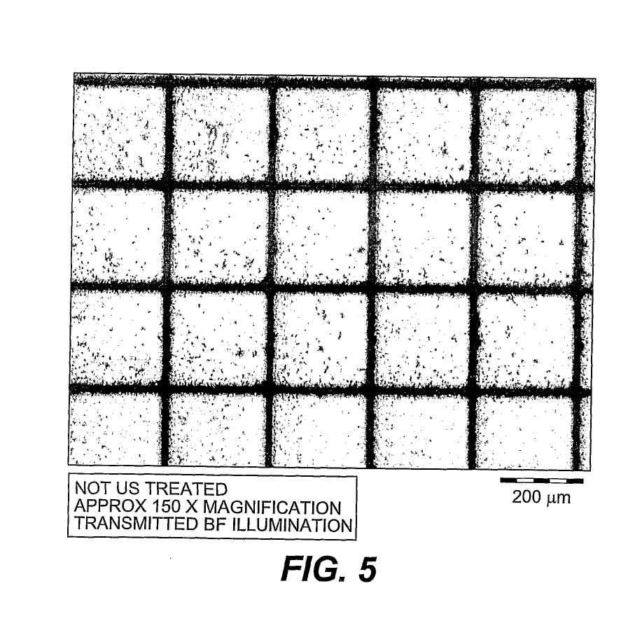

Sample 2 was processed in the same way, held vertically in the container but without any ultrasonic agitation. The mesh of Sample 2 (see FIG. 5) consisted of tracks with a sheet resistance of 0.19 Ω/square, with the mesh itself having a sheet resistance of 5.5 Ω/square. The transmission of this mesh was <70%.

As can be seen from FIGS. 4 and 5, the ultrasonic agitation had inhibited the adherence of unwanted silver nodules, either to the sides of the wire or in the background area.

1. A method of manufacturing a heating element having a desired pattern of conductive tracks forming a power dissipative conductive track pattern with a desired resistivity and power output, the method comprising providing a photosensitive or pressure-sensitive element comprising:
a support having coated on at least one side thereof a photosensitive or pressure-sensitive layer, which is capable of, upon imagewise radiation or pressure exposure according to the desired pattern and development of the resulting latent image, providing a metal image according to said desired pattern;
imagewise radiative or pressure-exposing the layer of said element according to a desired conductive pattern to form a latent image in said layer; and
developing said element to form a conductive metal pattern, corresponding to the pattern of said latent image, on said support, wherein the developing comprises conventional development and one or more of physical, electrochemical or thermal development.

2. A method as claimed in claim 1, wherein said coated support comprises a photosensitive or pressure-sensitive metal salt dispersed in a carrier composition.

3. A method to as claimed in claim 2, wherein said photosensitive or pressure-sensitive metal salt is a silver salt.

4. A method as claimed in claim 3, wherein said silver salt is one or more of silver chloride, silver bromide, silver chlorobromide and silver chlorobromoiodide

5. A method as claimed in claim 2, wherein said carrier composition comprises gelatin.

6. A method as claimed in claim 1, wherein said photosensitive or pressure-sensitive layer is a silver halide emulsion in a hydrophilic binder or polymer.

7. (canceled)

8. A method as claimed in claim 1, wherein said coated support comprises a pressure-sensitive silver halide, a secondary source of silver ions in catalytic proximity to said silver halide and an incorporated developer composition, whereby upon pressure-exposure and heating a conductive metal track is formed according to said desired track pattern.

9. A method as claimed in claim 1, wherein said conductive tracks have a line width of 25 μm or less.

10. A method as claimed in claim 1, wherein said coated support is a flexible, transparent coated support.

11. A method as claimed in claim 1, wherein the unexposed areas of said photosensitive or pressure-sensitive layer are removed during the development step.

12. A method as claimed in claim 1, wherein said support is selected from the group consisting of polyethylene terephthalate, polyethylene naphthalate, cellulose triacetate, glass, polycarbonates, acrylic esters, polyvinylacetals and polyurethanes.

13. A method as claimed in claim 1, wherein said pattern is a regular mesh pattern having a mesh diameter of 2 mm or less.

14. A method as claimed in claim 1, wherein said heating element has an optical transmission of at least 90%.

15. A heating element obtainable by the method of claim 1.

16.-25. (canceled)
